(19) United States
(12) Patent Application Publication
(10) Pub. No.: US 2007/0108595 A1
(43) Pub. Date: May 17, 2007

(54) Semiconductor device with integrated heat spreader

(75) Inventor: Gamal Refai-Ahmed, Markham (CA)

Correspondence Address: ATTN: Matthew Zischka;Smart & Biggar, Suite 1500, Box 111, 438 University Avenue, Toronto, M5G 2K8, CA

(73) Assignee: ATI Technologies Inc.

(21) Appl. No.: 11/274,139

(22) Filed: Nov. 16, 2005

(51) Int. Cl. H01L 23/34

(52) U.S. Cl. 257/706

(57) ABSTRACT

A semiconductor device includes a die, a substrate, a heat spreader and a plurality of signal interconnects extending from the die. The heat spreader has a base and a plurality of fins. The heat spreader is mounted on the substrate in such a way that the base of the head spreader is in thermal communication with the die. The fins protrude downwardly into the substrate conducting heat away from the die and into the substrate.

### FIELD OF THE INVENTION

The present invention relates generally to semiconductor devices, and more particularly to semiconductor devices that include an integrated heat spreader.

### BACKGROUND OF THE INVENTION

Current semiconductor devices typically include a die, a substrate, one or more metallization layers, I/O pins or balls, a heat spreader and optionally a heat sink. The die contains the active circuitry of the device and a number of connections called die-pads. The die is typically mounted in a cavity within the substrate. One or more of the metallization layers include pads called bond-fingers that are used to interconnect the metallization layers to the die-pads. The metallization layers, in turn, route electrical connections within the chip package from the die to the I/O pins or balls.

The die-pads may be electrically coupled to the bond-fingers using conventional wire bonding, by connecting the pads to the bond-fingers by conductive wires. Alternatively, the die can be mounted with its active surface facing the substrate and the die-pads may connect to the bond-fingers using electrically conductive bumps extending from the die. As the active surface faces down, such semiconductor devices are often referred to as “flip chip” packages. Flip chip packages have several advantages over chip packages that use wire bonding. These include a smaller package area, lower signal propagation delays and better electrical performance, resulting from shorter connection lengths. Moreover, flip chip packages permit a larger number of I/O connections, as the die-pads are not restricted to the periphery of the die.

Metallization layers may be formed on one side or on both sides of the substrate. Substrates with metallization layers on only one side are known as single-sided chip packages, while double-sided chip packages have metallization layers on both sides of the substrate. Single-sided chip packages are preferred, as they require fewer metallization layers and fewer manufacturing steps. Single-sided chip packages also avoid plated through-holes (PTH) that provide electrical connections between metallization layers on opposite sides of the substrate in double-sided chip packages.

As noted, dies are typically contained within a cavity of the semiconductor device substrate. They are packaged either cavity-down or cavity-up. In a cavity-down configuration, the cavity in the substrate that contains the die will be facing down when the chip package is attached to a printed circuit board (PCB). Conversely, in a cavity-up package, the cavity will be on top when the chip package is attached. Cavity-down packages do not permit the cavity area to be used for I/O pins while cavity-up configurations do not have such limitations. Thus, for a given number of I/O pins, a cavity-up package would need a smaller size to accommodate the I/O pins than a cavity-down package.

In modern semiconductor packages, the continued push for higher performance and smaller size leads to higher operating frequencies and increased package density (more transistors). However, the circuitry on such a die consumes an appreciable amount of electrical energy during device operation. This energy invariably turns into heat that must be removed from the package. Conventional heat spreaders and heat sink attachments may be used to dissipate the heat generated by the die. However, as the majority of the heat is generated in the die, the relative distribution of thermal energy within the chip package is often quite uneven.

Accordingly, there is a need for a semiconductor package with features that mitigate the effects of increased power density and uneven thermal energy distribution that is common in modern semiconductor packages.

### SUMMARY OF THE INVENTION

A semiconductor device according to the present invention includes a die, a substrate, a heat spreader and a plurality of signal interconnects extending from the die. The heat spreader has a base and a plurality of fins. The heat spreader is mounted on the substrate in such a way that a thermal conduction path exists between the base of the head spreader and the die. The fins protrude downwardly into the substrate conducting heat away from the die and into the substrate.

Optionally, the die can be embedded within a cavity in the substrate formed on the top surface of the substrate. This allows the entire bottom surface of the device to be used for I/O pins. The substrate can be single-sided if desired, to simplify the device manufacturing process.

In accordance with an aspect of the present invention, there is provided a semiconductor device including a substrate defining a cavity, a die having a circuit formed thereon, a plurality of signal interconnects, and a heat spreader. The heat spreader includes a base and a plurality of fins extending from the base. The base is mounted atop the substrate and in thermal communication with the die. The fins extend into the substrate to direct heat away from the die and into the substrate.

In accordance with another aspect of the present invention, there is provided a method of operating a semiconductor device. The semiconductor device includes a die, a substrate, I/O pins and signal interconnects connecting the die and the I/O pins. The method includes forming recesses in the substrate and attaching a heat spreader. The heat spreader has a base, and a plurality of fins protruding from the base into the recesses in the substrate to conduct heat away from the die into the substrate.

Other aspects and features of the present invention will become apparent to those of ordinary skill in the art upon review of the following description of specific embodiments of the invention in conjunction with the accompanying figures.

### BRIEF DESCRIPTION OF THE DRAWINGS

In the figures which illustrate by way of example only, embodiments of the present invention,

FIG. 1 is a vertical cross section of a conventional semiconductor device with a single-sided substrate, a conventional heat spreader and a heat sink;

FIG. 2 is a cross section of a semiconductor device with an integrated heat spreader assembled, exemplary of an embodiment of the present invention;

FIG. 3 is a more detailed cross section of the semiconductor device shown in FIG. 2 before the heat spreader is mounted;

FIG. 4A is a perspective view of the heat spreader shown in FIG. 2;

FIG. 4B is a bottom view of the heat spreader shown in FIG. 4A;

FIG. 4C vertical cross section the heat spreader along IV-IV, shown in FIG. 4A; and

FIG. 5 is a cross section of a further semiconductor device with attached heat sink, exemplary of a further embodiment of the present invention.

### DETAILED DESCRIPTION

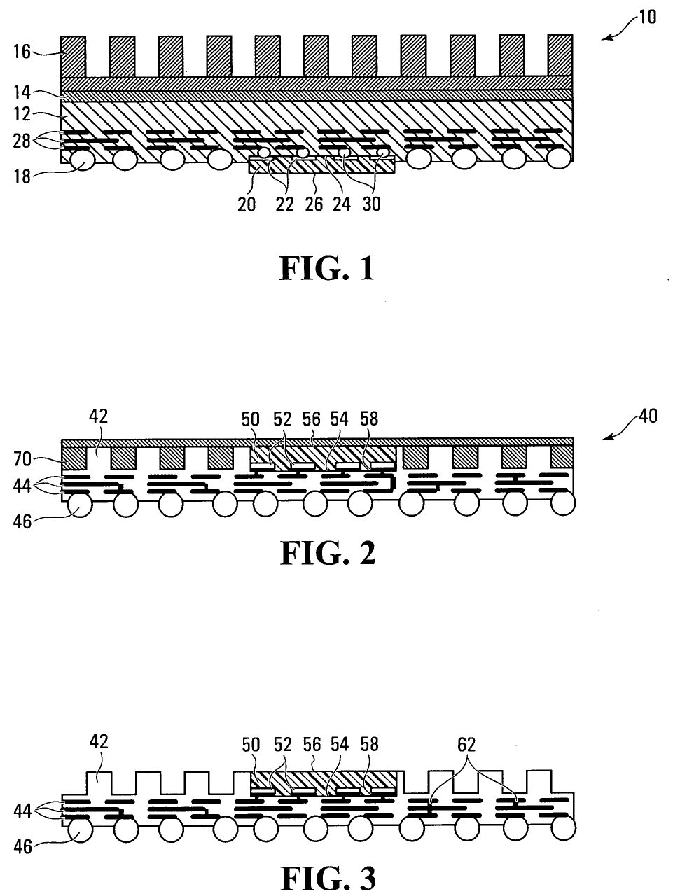

A conventional flip chip semiconductor device 10 is shown in FIG. 1. Device 10 includes a substrate 12, a die 20, package pins 18, a heat spreader 14, and a heat sink 16. Die 20 is a piece of silicon wafer that contains the active circuitry of device 10. The surface of die 20 that contains the circuitry is called the active surface 24 while the opposite surface is known as the inactive surface 26. Die 20 has a number of I/O connections called die-pads 22, which are used to connect input and output signals to the die 20.

Substrate 12 is made up of a core material that may be metal, ceramic, or an epoxy core, and one or more of conductive layers laminated thereon, called metallization layers 28. Metallization layers 28 are used to route signal connections within the package between die-pads 22 and package pins 18. A layer made from a dielectric material insulates metallization layers 28 from each other. Metallization layers 18 can be formed on just one surface of substrate 12 or on both top and bottom surfaces. Exemplary substrate 12 includes metallization layers 28 formed on only one surface. Such a substrate is known as a single-sided substrate.

Die 20 is electrically coupled to the substrate 12 by signal connections between die-pads 22 and connection pads on the metallization layers 28 called bond-fingers (not shown). Die 20 is attached with its active surface 24 facing the substrate 12 and aligned so that the die-pads 22 can be electrically coupled with the bond-fingers using conductive bumps 30 extending from die-pads 22. Unlike in wire bonding where the inactive surface of the die is placed on the substrate, here the die is “flipped” with the active surface 24 facing substrate 12. As noted earlier, such an attachment is called ‘flip chip’. Flip chip attachments involve shorter signal paths between die-pads 22 and the bond-fingers and therefore offer better electrical performance and smaller area requirements. Unlike in wire bonding, in flip chip connections, under bump metallization (UBM—not shown in FIG. 1) is formed first on die-pads 22 before conductive bumps 30 are formed. Forming the UBM involves removing oxidation layers from die-pads 22 and depositing metal instead to ensure that good electrical connections can be established between die-pads 22 and conductive bumps 30.

Device 10 also includes a conventional heat spreader 14, used to spread the heat generated by die 20 across a larger surface area. Heat spreader 14 is generally flat and mounted atop substrate 12. Heat sink 16 can be attached to the heat spreader 14, to allow cooling by convection. Thermal vias (not shown) may couple die 20 to heat spreader 14.

In conventional single-sided flip chip device 10, the cavity containing die 20 is facing down when the chip package is attached to a printed circuit board (PCB). Such a package is called a cavity-down package. Cavity-down packages make room for the cavity at the bottom of package, which is disadvantageous as it limits the number of pins for the package.

FIG. 2 shows a semiconductor device 40 that is exemplary of an embodiment of the present invention. Device 40 includes a substrate 42, a die 50, package pins 46, and an integrated heat spreader 70. FIG. 3 is a more detailed cross-section of device 40 without heat spreader 70. As shown in FIG. 3, semiconductor device 40 also has a single-sided substrate 42 with one or more metallization layers 44 formed on only the bottom surface. Single-sided substrates are advantageous as they lead to fewer manufacturing steps and efficient utilization of metallization layers.

The metallization layers 44 may be connected to each other with micro-vias 62. However, plated through-holes (PTH), which span the entire height of the substrate to provide connections between metallization layers on opposite sides of a substrate, are conveniently avoided.

Die 50 is embedded in the substrate 42, which leads to a smaller package height. Die 50 is attached with its active surface 54 facing down and die-pads 52 connecting die 50 to metallization layers 44. Conductive bumps, as those used in device 10 of FIG.1 are not required in device 40. Instead, a standard micro-via formation process is used to couple a UBM 58 formed on the die-pads 52 to the metallization layers 44. Thus, device 40 retains all the advantages of a flip chip interconnection with the added benefit that conductive bumps are eliminated.

In device 40, the cavity that contains die 50 is on the top surface of the substrate 42, unlike in the conventional device 10 of FIG. 1. Device 40 is therefore not a cavity-down package but rather a cavity-up package, which allows use of the entire bottom surface of the package for I/O pins 46.

Heat spreader 70 is in thermal communication with die 50. In the depicted embodiment a portion of heat spreader 50 is in direct contact with the inactive surface of die 50. Of course, heat spreader could be connected to die 50 in other ways. For example, heat spreader 70 could be in communication with die 50 by way of an intermediate thermal conductive layer; thermal vias; or in any other manner appreciated by a person of ordinary skill in the art.

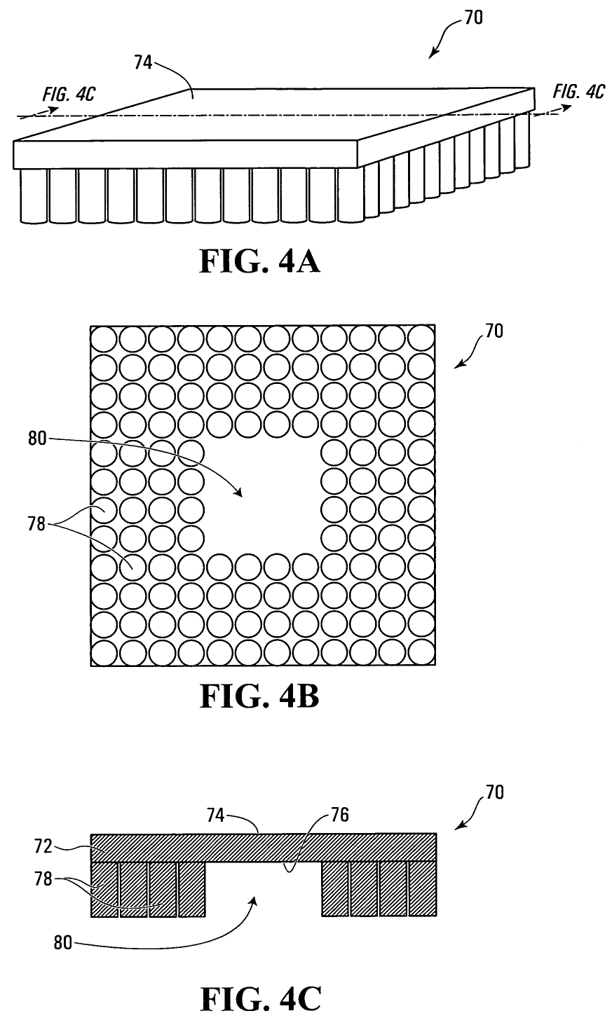

FIGS. 4A, 4B and 4C show different views of an exemplary embodiment of heat spreader 70. Heat spreader 70 includes a base 72 and a plurality of fins 78. Base 72 is generally rectangular and has a top surface 74 and a bottom surface 76. Fins 78 extend from bottom surface 76 of base 72. Fins 78 are arranged in a rectangular grid pattern, as shown in FIG. 4B. The grid pattern exposes a contiguous, generally flat area 80 at the center of bottom surface 76 of base 72. In the depicted embodiment, the generally flat area 80 shown in FIG. 4B is sufficiently large and generally planar to allow the whole inactive surface 56 of die 50 to make physical contact with the bottom surface 76 of the base. Heat spreader 70 is mounted on the substrate 42 with its fins 78 protruding down into the substrate 42. The heat spreader can be made of graphite, diamond, copper, aluminum or any other suitable material with good thermal conductivity. Heat spreader 70 is vertically aligned with the substrate 42 in such a way that the generally flat area 80 of the bottom surface 78 of base 72 is in direct thermal connection with the inactive surface 56 of the die 50. A thermal interface material (TIM) may be used as a thermal adhesive between the inactive surface 56 of the die 50 and the generally flat area 80. The substrate may have recesses or holes for the fins. The holes are of slightly smaller dimension than the actual fins. Upon attachment, the fins are placed in the recesses and conventional substrate bonding techniques are used to attach the heat spreader. Alternately, reactive multi-layer foils may be used to bond the heat spreader to the substrate using techniques described in US Publication No. 2003/0164289 by Weihs et al. which is hereby incorporated by reference. These techniques allow reactive foils to be used as localized heat sources, eliminating the need for standard furnace, torch or laser.

An exemplary embodiment of the heat spreader 70 has generally cylindrically shaped fins 78 and a substantially planar base as shown in FIGS. 4A-4C. The base is rectangular in shape. It is easy to see that a circular or elliptical shaped base can be used, or that the fins may take another shape. For example, the fins may have rectangular, square or oval cross-sections. Similarly, the cross-sections need not be uniform.

The dimensions of heat spreader 70 will, of course, depend on the dimensions of the device 40. The height of the fins 70 may for example be about 90% to 95% of the minimum die height. For a semiconductor package with dimensions of 36 mm by 36 mm by 1.8 mm and a die size of 15 mm by 15 mm the heat sink can have a base thickness of about 0.16 mm, a fin height of about 0.84 mm with a fin diameter of about 0.4 mm. The fins 78 can be arranged as a rectangular grid of 14 by 18 fins with the generally flat area 80 in the middle of the bottom surface 76 being equivalent in size to a 4 by 6 grid of fins.

In operation, circuitry on die 50 in device 40 consumes a certain amount of electrical energy. The energy invariably turns into heat that must be removed. Heat spreader 70 provides an efficient thermal conduction path for the heat generated mainly by die 50. The heat generated by the die flows primarily through the generally flat area 80 in contact with the inactive surface 56 of die 50, and is then spread throughout the package by base 72 and fins 78. This facilitates uniform heat dissipation across the surface of the package although the heat from die 50 is concentrated at die 50, and often non-uniform. Conveniently, the use of example heat spreader 70 leads to better thermal performance than the use of a conventional one such as the heat spreader 14 shown in FIG. 1, by lowering the temperature gradient between the die 20 and substrate 42. The heat flux is also reduced due to the large surface area of the heat spreader 70.

In another embodiment, base 72 of heat spreader 70 may have additional fins extending upwardly from the top surface 74. In this case the heat spreader also performs the functions of a heat sink by allowing cooling by convection.

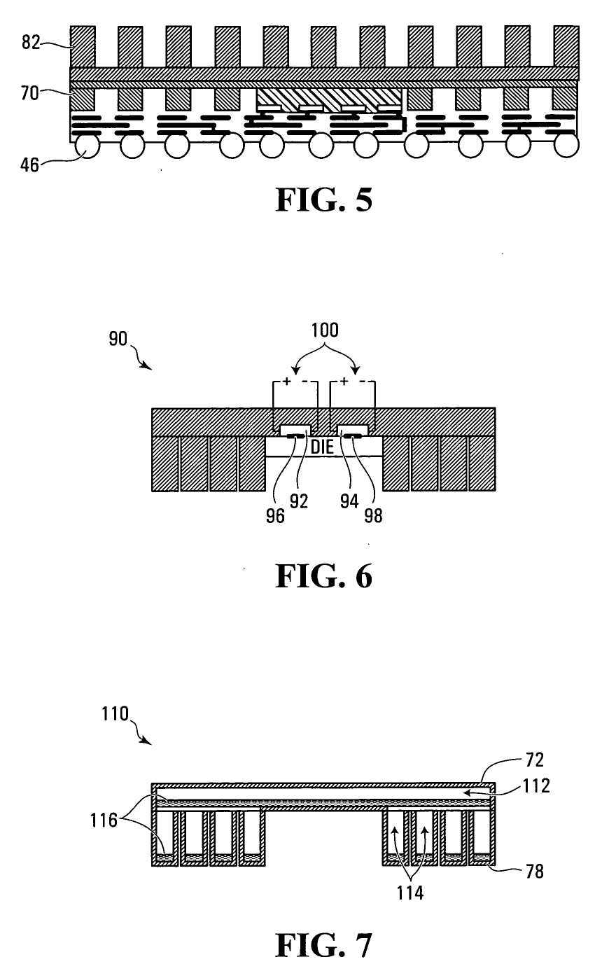

In yet another embodiment, a conventional heat sink 82 may be attached on top of the heat spreader 70 as shown in FIG. 5. Thermal Interface Material (TIM) such as thermal grease (not shown) may be used to attach the conventional heat sink 82 on top of the heat spreader 70. The conventional heat sink may, for example, be an extruded heat sink, a folded fin heat sink or a vapor chamber heat sink.

Among the more interesting implementations of the heat spreader contemplated are thermoelectric cooling (TEC) and the use vapor chambers inside the heat spreader. Thermoelectric cooling works by exploiting a thermodynamic property known as the Peltier Effect. The typical thermoelectric module is manufactured using two thin ceramic wafers with a series of P and N doped bismuth-telluride semiconductor material between them. The ceramic material on both sides of the thermoelectric provides rigidity and electrical insulation. The N type material has an excess of electrons, while the P type material has a deficit of electrons. As electrons move from P to N they transition to a higher energy state (absorbing heat energy), and as they move from N to P, attain a lower energy state (giving off heat energy) thereby providing cooling to one side. Thermoelectric micro-coolers (μ-TEC) are known and commercially available. As shown in FIG. 6, one or more μ-TECs 92, 94 can be embedded in the base 72 of the heat spreader 70, and in thermal communication with localized regions 96, 98 of the die where the heat dissipation is especially high. The required DC power source 100 can be supplied externally to ease the manufacturing process.

The heat spreader can also accommodate an optional vapor chamber as shown in FIG. 7. Liquid 116 such as water is introduced into a grooved rectangular volume (chamber) 112 within the base 72 of the spreader 70 to form the vapor chamber. Heat generated in the die causes the water molecules evaporate. When the vapor condenses, heat is given off at the ceiling of the chamber thereby achieving the desired cooling; and the process starts again. Additionally, the fins 78 could also be made hollow and water introduced, so as to form heat-pipes 114. Pipes 114 adjoin the vapor chamber in the base of spreader. Heat is transferred upward through the pipes to the adjoining vapor chamber.

Numerous variations of shapes and sizes of the base or the fins, different constellations of fin patterns, as well as different shapes of the generally flat area will become immediately apparent to one skilled in the art without departing from the scope of the claims appended herein.

Of course, the above described embodiments are intended to be illustrative only and in no way limiting. The described embodiments of carrying out the invention are susceptible to many modifications of form, arrangement of parts, details and order of operation. The invention, rather, is intended to encompass all such modification within its scope, as defined by the claims.

What is claimed is:

1. A semiconductor device comprising:
a) a substrate defining a cavity;
b) a die having an integrated circuit formed thereon, said die received in said cavity;
c) a plurality of signal interconnects extending from said die; and
d) a heat spreader comprising a base and a plurality of fins extending downwardly from said base, said base mounted atop of said substrate and in thermal communication with said die, said fins extending into said substrate to direct heat generated by said die into said substrate.

2. The semiconductor device of claim 1, wherein said base is substantially planar.

3. The semiconductor device of claim 2, wherein the shape of said base is a polygon.

4. The semiconductor device of claim 3, wherein said base has a thickness of 0.1 mm or greater.

5. The semiconductor device of claim 1, wherein said fins are generally cylindrical in shape.

6. The semiconductor device of claim 5, wherein the ratio of fin-diameter to fin-height ranges from about 1:10 to about 1:1.

7. The semiconductor device of claim 1, wherein said die is in direct contact with said base of said heat spreader.

8. The semiconductor device of claim 1, wherein said heat spreader has additional fins extending upwardly from said base.

9. The semiconductor device of claim 1, wherein said die comprises an active surface and an inactive surface, said die is attached to said substrate with said active surface facing said substrate, and said plurality of signal interconnects form electrical coupling between said die and said substrate.

10. The semiconductor device of claim 1, wherein said die comprises an active surface and an inactive surface, said inactive surface is attached to said substrate, and said plurality of signal interconnects form electrical coupling between said die and said substrate.

11. The semiconductor device of claim 1 wherein said substrate comprises a top surface and a bottom surface, with one or more metallization layers formed only on said bottom surface

12. The semiconductor device of claim 11, wherein said cavity in said substrate is formed on said top surface

13. The semiconductor device of claim 11, wherein said cavity in said substrate is formed on said bottom surface

14. The semiconductor device of claim 1, wherein said substrate comprises a top surface and a bottom surface, with one or more metallization layers formed on said top surface.

15. The semiconductor device of claim 14, wherein said cavity extends from said top surface of said substrate.

16. The semiconductor device of claim 14, wherein said cavity extends from said bottom surface of said substrate.

17. The semiconductor device of claim 1 wherein said substrate comprises a top surface and a bottom surface, with one or more metallization layers formed on both said top surface and said bottom surface

18. The semiconductor device of claim 1, further comprising a heat sink attached to said heat spreader

19. The semiconductor device of claim 1, further comprising one or more thermoelectric coolers in thermal communication with said die.

20. The semiconductor device of claim 1, further comprising vapor chamber formed within said base of said heat spreader.

21. The semiconductor device of claim 20, further comprising heat pipes formed within said fins of said heat spreader, and in communication with said vapor chamber.

22. A combined heat spreader and heat sink comprising:
a) a base made from thermally conductive material, said base comprising a top surface and a bottom surface;
b) a plurality of fins made from thermally conductive material, said fins extending from parts of said bottom surface of said base; and
c) a plurality of fins made from thermally conductive material, said fins extending from parts of said top surface of said base.

23. A method of operating a semiconductor device, said device comprising a die, a substrate, I/O pins, and a plurality of signal interconnects extending from said die and connecting to said pins, said die placed in a cavity in said substrate, said method comprising:
a) forming a plurality of recesses in said substrate; and
b) attaching a heat spreader comprising a base and a plurality of fins to said substrate with said base in thermal contact with said die, and said fins protruding from said base and into said recesses to conduct heat away from said die and into said substrate.
